(19) United States
(12) Patent Application Publication
(10) Pub. No.: US 2008/0029824 A1
(43) Pub. Date: Feb. 7, 2008

(54) ESD POWER CLAMP IN TRIPLE WELL

(75) Inventors: Arnold E. Baizley, Underhill, VT (US); Philippe Hauviller, Itteville (FR); Steven H. Voldman, South Burlington, VT (US)

Correspondence Address: HOFFMAN, WARNICK & D'ALESSANDRO LLC, 75 STATE ST, 14TH FLOOR, ALBANY, NY, 12207, US

(73) Assignee: INTERNATIONAL BUSINESS MACHINES CORPORATION, Armonk, NY (US)

(21) Appl. No.: 11/461,831

(22) Filed: Aug. 2, 2006

(51) Int. Cl. H01L 29/76

(52) U.S. Cl. 257/371

(57) ABSTRACT

A power clamp in a triple well is disclosed. A metal oxide semiconductor (MOS) varactor is used in a triggering circuit and is positioned in a first N type well. An N-channel field effect transistor is positioned in a P-type well. A P-channel field effect transistor is positioned in a second N-type well. The first N-type well is electrically isolated from the second N-type well, and electrically contacts the substrate of the power clamp.

### FIELD OF THE INVENTION

The invention relates generally to electrostatic discharge (ESD) protection, and more particularly, to ESD power clamps in a triple well.

### BACKGROUND ART

As the integrated circuit (IC) processing technology sizes are reduced, an IC connected to external ports becomes more susceptible to electrostatic discharge (ESD) pulses from, e.g., the operating environment. Approaches to solve the ESD problems include zener diodes, metal oxide varistors (MOVs), transient voltage suppression (TVS) diodes, and regular complementary metal oxide semiconductor (CMOS) or bipolar clamp diodes, among which an ESD power clamp design has become popular, because it can achieve both functional and ESD advantages. In image processing technology, it is desired that a resistor-capacitor (RC) triggered power clamp be positioned within a triple well. However, placing an RC triggered power clamp into a triple well using known technology may have, among others, two disadvantages. One is that an N type body of a MOS varactor (usually used to effect the capacitor of an RC triggered power clamp) will be shorted to N type implant of the triple well. The other is that in a mixed voltage interface, electrical connections of such power clamps must be changed to avoid electrical over-bias states. Present state of the art technology does not provide satisfactory solutions to the above problems.

### SUMMARY OF THE INVENTION

A power clamp in a triple well is disclosed. A metal oxide semiconductor (MOS) varactor is used in a triggering circuit and is positioned in a first N type well. An N-channel field effect transistor is positioned in a P-type well. A P-channel field effect transistor is positioned in a second N-type well. The first N-type well is electrically isolated from the second N-type well, and electrically contacts the substrate of the power clamp.

A first aspect of the invention provides a structure in a power clamp system within a triple well, the structure comprising: a substrate; a metal oxide semiconductor (MOS) varactor positioned in a first N type well; an N-channel field effect transistor positioned in a P-type well; and a P-channel field effect transistor positioned in a second N-type well; wherein the first N-type well is electrically isolated from the second N-type well, and the first N-type well electrically contacts the substrate.

A second aspect of the invention provides an integrated circuit coupled between a first power rail and a second power rail, the first power rail having a higher potential than that of the second power rail, the integrated circuit comprising: a triggering circuit including a resistor and a metal oxide semiconductor (MOS) varactor functioning as a capacitor, the resistor and the MOS varactor coupled in series between the first power rail and the second power rail; and an inverter chain including a P-channel field effect transistor (pFET) and an N-channel field effect transistor (nFET), the pFET being coupled to the first power rail through a level shifter; wherein a body of the pFET is connect to the first power rail and a body of the nFET is connected to the second power rail.

A third aspect of the invention provides a power clamp system, the power clamp system comprising: a power clamp device coupled between a first power rail and a second power rail, the first power rail having a potential higher than that of the second power rail, the power clamp device including: a substrate; a metal oxide semiconductor (MOS) varactor positioned in a first N-type well; and an inverter circuit including an N-channel field effect transistor positioned in a P-type well and a P-channel field effect transistor positioned in a second N-type well; wherein the first N-type well is electrically isolated from the second N-type well, and the first N-type well electrically contacts the substrate.

The illustrative aspects of the present invention are designed to solve the problems herein described and other problems not discussed, which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a circuit structure of a resistor-capacitor (RC) triggered power clamp system according to one embodiment of the invention.

FIG. 2 shows a cross-sectional view of part of the power clamp system of FIG. 1, according to one embodiment of the invention.

FIG. 3 shows an alternative embodiment of a power clamp system according to one embodiment of the invention.

FIG. 4 shows another alternative embodiment of a power clamp system according to one embodiment of the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

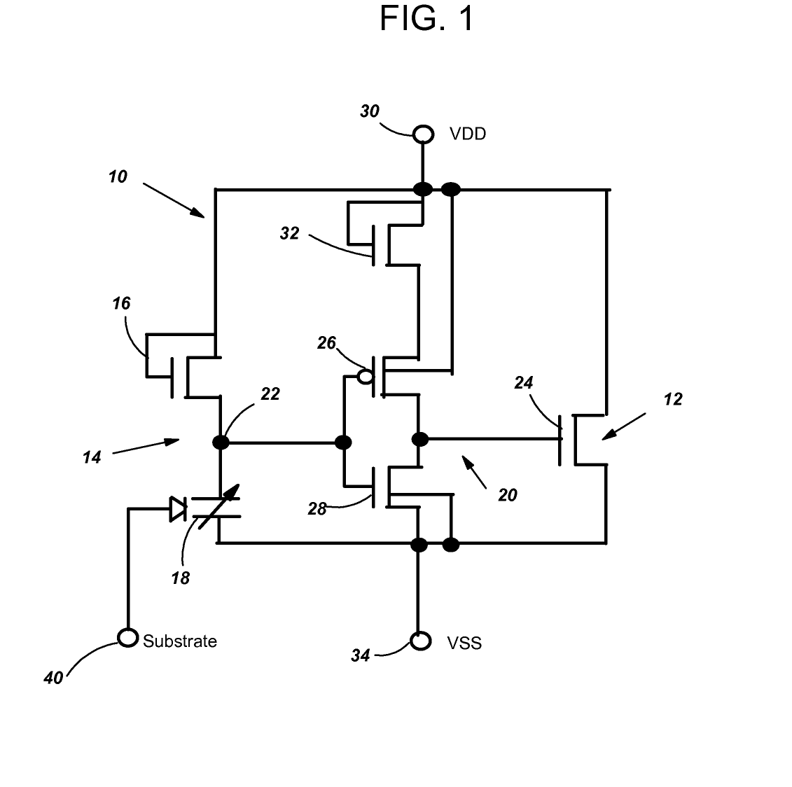

Turning to the drawings, FIG. 1 shows a circuit structure of an RC triggered power clamp system 10 according to one embodiment of the invention. Power clamp system 10 includes an N-channel field effect transistor (nFET) 12; a triggering circuit 14 including a resistor 16 and a capacitor 18; and an inverter chain 20 (one is shown). Inverter chain 20 is coupled between triggering circuit 14 and nFET 12. Specifically, the input of inverter chain 20 is coupled to an interconnect 22 between resistor 16 and capacitor 18, and the output of inverter chain 20 is coupled to gate 24 of nFET 12. Inverter (chain) 20 includes a P-channel field effect transistor (pFET) 26 and an nFET 28. Body of pFET 26 is coupled to positive power supply (VDD) 30; and body of nFET 28 is coupled to negative power supply (VSS) 34.

According to one embodiment, source pin of pFET 26 is coupled to VDD 30 through a level shifter 32. Level shifter 32 functions to lower the potential applied to the source pin of pFET 26. Any devices that can perform this function can be used to implement level shifter 32. According to one embodiment, level shifter 32 may be an nFET with the gate shorted to drain, as shown in FIG. 1. As such, the potential applied to the source pin of pFET 26 will be reduced by the threshold voltage of nFET 32, i.e., VDD−Vt of nFET 32.

According to one embodiment, an accumulation-mode metal oxide semiconductor (MOS) varactor (varactor) may be used to implement capacitor 18. Varactor 18 may be biased at potential of VSS, and an N⁻ type well of varactor 18 electrically contacts substrate 40 and may interact with substrate 40 through a diode.

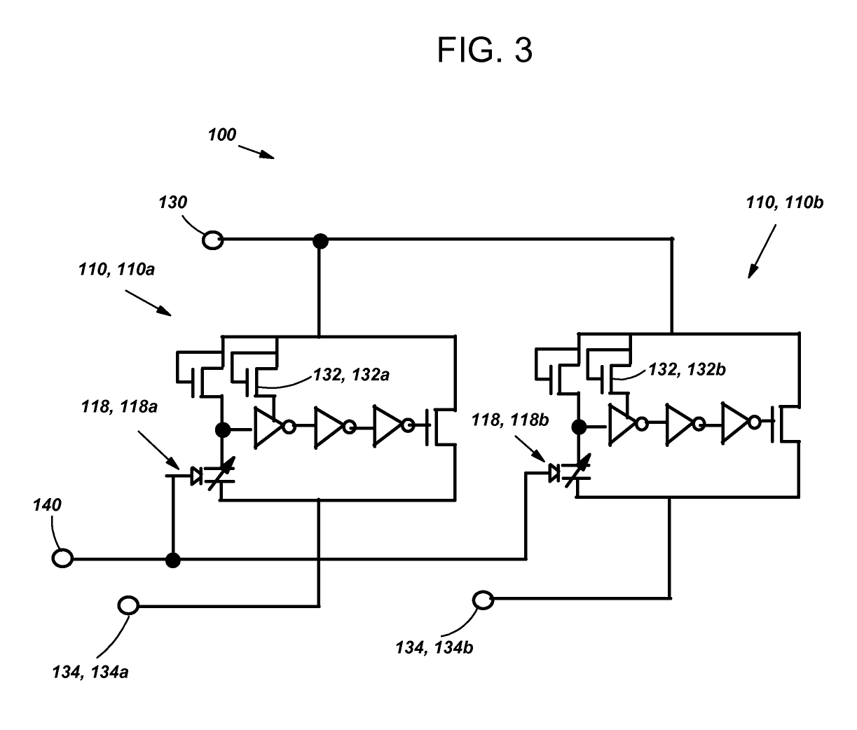

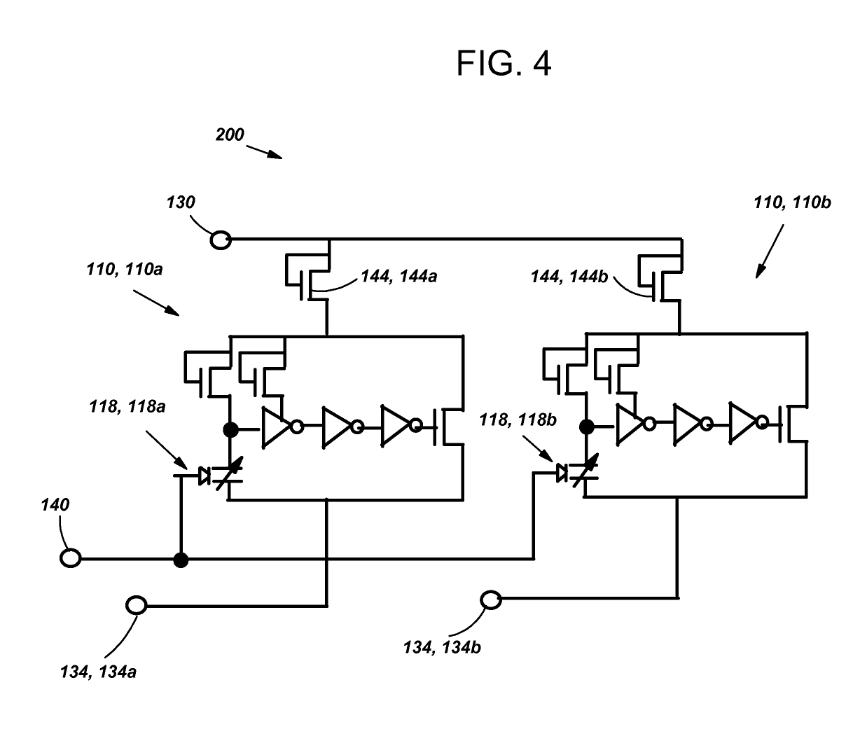

As is appreciated, inverter chain 20 may include any odd number of inverters coupled in series, and all are included in the invention. In the case the inverter chain 20 includes more than one inverter, level shifter 32 may be coupled only to the first inverter, as shown in FIGS. 3-4 (level shifter 132). In addition, VDD 30 and VSS 34 may represent any kinds of power supplies/potentials. The only requirement might be that power supply 30 and power supply 34 are of different potentials, with potential of power supply 30 higher than that of power supply 34.

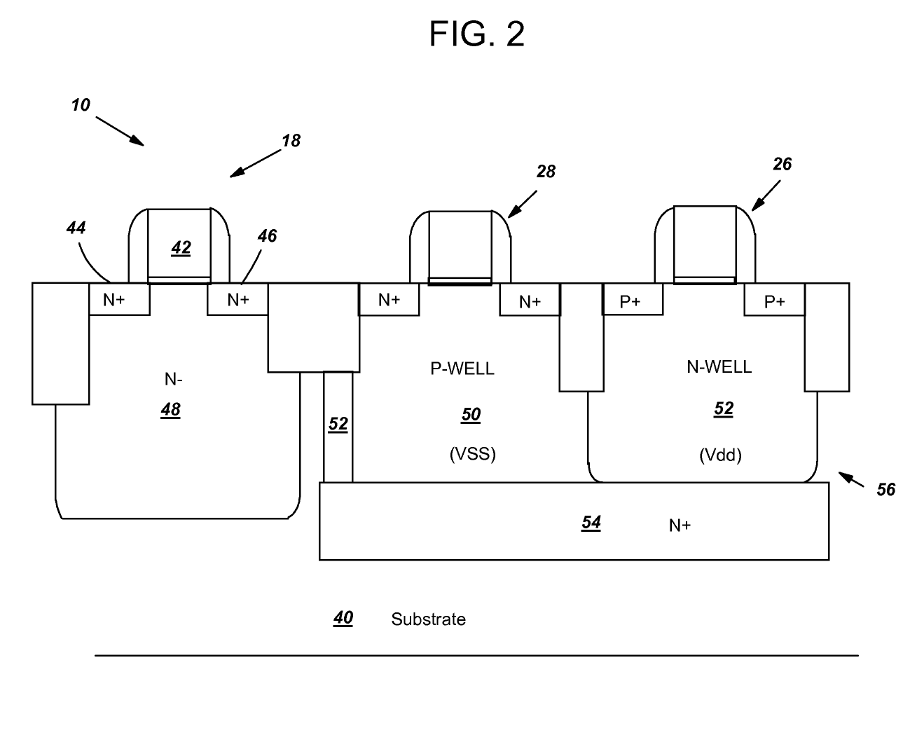

FIG. 2 shows a cross-sectional version of part of power clamp system 10 of FIG. 1, according to one embodiment. As shown in FIG. 2, MOS varactor 18 includes gate 42, diffusion regions 44 and 46 over N⁻ type well (NWELL) 48. NWELL 48 is positioned directly on and within substrate 40 such that NWELL 48 electrically contacts substrate 40 and a diode may exist between NWELL 48 and substrate 40 in operation. All NFETs of power clamp system 10, e.g., nFET 28 and nFET 32, are positioned in a P-type well (PWELL) 50 (only nFET 28 is shown). PFETs of power clamp system 10, e.g., pFET 26, are positioned in an N-type well (NWELL) 52. According to one embodiment, NWELL 52 is separated and electrically isolated from NWELL 48. PWELL 50 is separated from substrate 40 by N⁺ type doping region (layer) 54 and NWELL 52. Specifically, N⁺ type layer 54 is positioned above substrate 40 and below PWELL 50 and NWELL 52. As is appreciated, PWELL 50, NWELL 52 and N layer 54 constitute a merged triple well 56, and may be referred to as the P region, N region and N implant of triple well 56, respectively. PWELL 50 bias region is connected to VSS 34 (numeral 34 not shown); and NWELL 52 bias region is connected to VDD 30 (numeral 30 not shown).

FIG. 3 shows an alternative embodiment of a power clamp system 100 according to one embodiment of the invention. As shown in FIG. 3, power clamp system 100 may include multiple power clamp sub-systems 110 (two are shown), which may be similar to power clamp system 10 of FIG. 1. The multiple power clamp sub-systems 110 each is coupled between the same positive power supply (VDD) 130 and a respective one of multiple separate negative power supplies (VSS) 134 (134a, 134b). The multiple separate VSSs 134 may have the same potential or may have different potentials. In additions, the respective NWELLs of varactors 118 of power clamp sub-systems 110 electrically contact the same substrate 140.

FIG. 4 shows another alternative embodiment of a power clamp system 200 according to one embodiment of the invention. Power clamp system 200 may be similar to power clamp system 100 of FIG. 3, except that a level shifter 144 (144a, 144b), e.g., an nFET with gate shorted to drain, is positioned between VDD 130 and power clamp sub-system 110, respectively. An nFET 144 reduced the potential applied to the respective power clamp sub-system 110 by the threshold voltage (Vt) of the nFET 144. In addition, parameters, e.g., Vt, of nFETs 144 can be controlled/selected such that the potentials applied to each power clamp sub-system 110 are different.

The structures described above are used in integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A structure in a power clamp system within a triple well, the structure comprising:
a substrate;
a metal oxide semiconductor (MOS) varactor positioned in a first N type well;
an N-channel field effect transistor positioned in a P-type well; and
a P-channel field effect transistor positioned in a second N-type well;
wherein the first N-type well is electrically isolated from the second N-type well, and the first N-type well electrically contacts the substrate.

2. The structure of claim 1, wherein the MOS varactor is biased at a potential of a negative power supply (VSS).

3. The structure of claim 1, wherein a bias region of the P-type well is connected to a negative power supply (VSS).

4. The structure of claim 1, wherein a bias region of the second N-type well is connected to a positive power supply (VDD).

5. The structure of claim 1, further comprising an N-type layer positioned above the substrate and below the P-type well and the second N-type well.

6. The structure of claim 5, wherein the P-type well, the second N-type well and the N-type layer constitute a triple well.

7. The structure of claim 5, wherein the P-type well is separated from the substrate by the N-type layer and the second N-type well.

8. An integrated circuit coupled between a first power rail and a second power rail, the first power rail having a higher potential than that of the second power rail, the integrated circuit comprising:
a triggering circuit including a resistor and a metal oxide semiconductor (MOS) varactor functioning as a capacitor, the resistor and the MOS varactor coupled in series between the first power rail and the second power rail; and
an inverter chain including a P-channel field effect transistor (pFET) and an N-channel field effect transistor (nFET), the pFET being coupled to the first power rail through a level shifter;
wherein a body of the pFET is connect to the first power rail and a body of the nFET is connected to the second power rail.

9. The integrated circuit of claim 8, wherein the MOS varactor is biased at a potential of the second power rail.

10. The integrated circuit of claim 8, wherein a body of the MOS varactor contacts a substrate of the power clamp system.

11. A power clamp system, the power clamp system comprising:
a power clamp device coupled between a first power rail and a second power rail, the first power rail having a potential higher than that of the second power rail, the power clamp device including:
a substrate;
a metal oxide semiconductor (MOS) varactor positioned in a first N-type well; and
an inverter circuit including an N-channel field effect transistor positioned in a P-type well and a P-channel field effect transistor positioned in a second N-type well;
wherein the first N-type well is electrically isolated from the second N-type well, and the first N-type well electrically contacts the substrate.

12. The power clamp system of claim 11, wherein the MOS varactor is biased at a potential of the second power rail.

13. The power clamp system of claim 11, wherein a bias region of the P-type well is connected to the second power rail.

14. The power clamp system of claim 11, wherein a bias region of the second N-type well is connected to the first power rail.

15. The power clamp system of claim 11, further comprising an N-type layer positioned above the substrate and below the P-type well and the second N-type well.

16. The power clamp system of claim 15, wherein the P-type well, the second N-type well and the N-type layer constitute a triple well.

17. The power clamp system of claim 15, wherein the P-type well is separated from the substrate by the N-type layer and the second N-type well.

18. The power clamp system of claim 11, further including a second power clamp device, the second power clamp being coupled between the first power rail and a third power rail.
